(19) United States
(12) Patent Application Publication
(10) Pub. No.: US 2004/0145876 A1
(43) Pub. Date: Jul. 29, 2004

(54) Method for shielding an electric circuit created on a printed circuit board and a corresponding combination of a printed circuit board and a shield

(76) Inventor: J?ouml;rg Romahn, (US)

Correspondence Address: MORRISON & FOERSTER LLP, 1650 TYSONS BOULEVARD, SUITE 300, MCLEAN, VA, 22102, US

(21) Appl. No.: 10/478,328

(22) PCT Filed: May 17, 2002
(86) PCT No.: PCT/DE02/01883

(30) Foreign Application Priority Data
May 21, 2001 (DE) 101 25 746.5

(51) Int. Cl. H05K 7/02; H05K 7/06; H05K 7/08; H05K 7/10

(52) U.S. Cl. 361/760

(57) ABSTRACT

The invention relates to a method for shielding an electric circuit created on a printed circuit board (1) comprising a number or components (2). According to said method, a first electrically insulating layer (3) is applied to the whole surface of the printed circuit board (1) and a second earthed, electrically conductive layer (4), which acts as a shield, is then applied to the whole surface of said first electrically insulating layer (3), in such a way that suitable recesses (5) corresponding to the number of components are configured, The invention also relates to a corresponding combination of a printed circuit board (1), on which at least one electric circuit comprising a number of components (2) is created and a first electrically insulating layer (3) with a second earthed layer (4), which covers the whole surface and acts as a shield.

Method for shielding an electric circuit created on a printed circuit board and a corresponding combination of a printed circuit board with a shield

The invention relates to a method for shielding an electric circuit created on a printed circuit board. Elements which serve for shielding electric, high-frequency, radiating circuits are generally made of metallic materials, which are for example soldered on. As an alternative, metallized plastic housings may also be used. These are applied or their contacts are established on the printed circuit board by means of dispensing strips. However, these plastic housings are usually expensive on account of production, for which reason they are used only little. Furthermore, the previously used shielding elements have a geometry which is dimensionally quite stable. They form a kind of dimensionally fixed housing. In the case of an electric circuit created on a printed circuit board, there are usually components of different heights. In the case of metallic shielding, it must be ensured that all the components are at an adequate distance from the metallic shielding in order to avoid a short circuit. As an alternative, an intermediate insulating layer could be introduced. The housing serving for shielding is therefore shaped in such a way that, even after it has been mounted onto the circuit, an additional safety clearance between the housing and the individual components is ensured.

There have so far been essentially two basic forms of shielding. One is that shielding is provided in the form of a shroud which is fitted over the electric circuit to be shielded. This shroud is generally fixed on the printed circuit board by means of screws. As an alternative to this, it may also be soldered onto the printed circuit board. A disadvantage of this form is that this shroud can only be mounted after the functional capability of the electric circuit has been tested. Mechanical loads possibly occurring in the case of fixing by means of screws or thermal loads in the case of soldering on mean that there is always the risk of the electric circuit being damaged. A second possible way of forming shielding is to provide a frame which is soldered onto the printed circuit board and is closed by a suitable cover after the functional capability of the electric circuit has been tested. In comparison with the variant first presented, this possible form has the advantage that, in the case of a repair, the electric circuit is quite easily accessible by removal of the cover. However, a disadvantage arises in this case due to the possibly resultant unsatisfactory fastening of the cover, which may also be able to fall off or detach itself in an uncontrolled or unintentional manner if allowance is made for its easy removal.

Such shields are used for example for technologies such as DECT, GSM and in the case of other baseband circuits as well. Furthermore, they are also used for radio-frequency circuit parts.

A disadvantage of the forms of shields explained by way of example for electrical lines is that, as already briefly mentioned, the shield must be arranged with an adequate safety clearance over the highest component of the electric circuit in order to avoid possible short-circuits to electrically conductive component connections. The necessary safety clearance is generally several 1/10 mm, but at least 0.2 mm. Apart from the suitable safety clearance, the dimensionally stable configuration of the shield is also important here in order for the shield not to deform, whether by bending or buckling, during handling. If a shroud is used, allowance must also be made here for the shroud to have a tolerance of up to 0.5 mm.

A further disadvantage in the case of the forms of shields that are known and mentioned here by way of example can be seen in that mechanical stresses occur when there are strong temperature variations. These stresses act in turn on the printed circuit board and thereby possibly strain the soldered connections for example. To this extent, locations that are liable to require repair are produced as a result. Furthermore, in the event of a rapid increase in temperature, there is the risk of condensation forming on the electric circuit and the shield, which can lead to malfunctions ranging up to total failure of the electric circuit, in particular in the case of high-impedance electric circuits. Moisture occurring can cause short-circuits.

It was an object of the invention to provide a method for shielding a circuit created on a printed circuit board with the aid of which the aforementioned disadvantages of the shields previously used can be obviated simply and quickly.

This object is achieved by the independent claim 1. Further advantageous embodiments of the method according to the invention are presented in the corresponding subclaims.

According to claim 1, a method for shielding an electric circuit created on a printed circuit board comprising a number of components is provided, a first, electrically insulating layer being applied to the whole surface of the printed circuit board and a second, grounded, electrically conductive layer, which acts as a shield, being applied to the whole surface of the first, electrically insulating layer in such a way that suitable recesses corresponding to the number of components are provided.

In a particularly preferred embodiment of the method according to the invention, the combination of the first, electrically insulating layer with the second, grounded, electrically conductive layer, the second layer having corresponding recesses for the components, is an HDI layer. Here, HDI means “High Density Interconnection”. It is generally a printed circuit board on which the greatest possible number of connecting paths are created. The electrically conductive layer generally consists of copper and has a thickness in the range of 20 μm-60 μm, preferably approximately 30 μm. The electrically insulating layer preferably consists of an epoxy resin and has a thickness in the range of 20 μm-60 μm, preferably approximately 40 μm. This consequently produces an overall thickness in the range of 40 μm-110 μm, preferably of 4.0 μm-80 μm.

The major advantage of the method according to the invention can be seen in that it is possible to dispense with a shield in the form of a dimensionally stable housing, such as for example a shroud described at the beginning or a frame with a cover. The miniaturization of the components and the use of very short connections, in particular so-called “ball grids”, on integrated components allows adequate shielding of such an electric circuit created on the printed circuit board to be achieved already by the method according to the invention. It must be emphasized in this respect that the elements to be shielded of the electric circuit are predominantly the connection lines and to a lesser extent the components. The latter only have a usually negligible radiating efficiency. The connection lines on the other hand act as antennas. For this reason, the components themselves do not necessarily have to be shielded directly.

The method according to the invention makes the handling of the printed circuit board together with the circuit created on it much easier. The shield in the form of the two additionally applied layers is virtually fully integrated into the printed circuit board, so that no additional space for a shield has to be taken up. By comparison, if dimensionally stable metallic shields are used, an adequate safety clearance from the electric circuit or the individual components making up the circuit must be maintained in order to avoid the occurrence of short-circuits. So far, it has always been necessary to ensure when handling the printed circuit board together with the shield that no deformation of the shield that could possibly lead to the occurrence of short-circuits can occur. On the basis of the method according to the invention, this careful handling is no longer necessary.

The establishment of contacts of the individual components with the printed circuit board for the actual interlinking of the individual components with one another preferably takes place by means of laser contacting or a laser technique, preferably directly at the location of the corresponding component. Directly at the location of the component means here that the contact sites of the component are preferably arranged between it and the printed circuit board. So-called micro-vias are produced by means of a laser. These are so-called “blind holes”, i.e. bores which are of an extremely small depth. The bores necessary for establishing contacts are virtually punctiform, so that no air space can be created in the bores. Consequently, there is no capillary action. When establishing contacts by means of a soldering process, for example, it is consequently ensured that the soldering tin applied is not drawn away by a capillary action occurring or centrifugally removed by air that is present. Consequently, very solid and stable contact sites are obtained.

The second, grounded, electrically conductive layer, which acts as a shield, is applied according to the invention to the whole surface in such a way that suitable recesses corresponding to the number of components are provided. The fact that the contacting of the individual components with respect to the printed circuit board can be performed, as described, directly at the location of the respective components means that the necessary recesses can preferably be kept as small as possible, so that greatest possible shielding is obtained.

A further advantage of the present invention can be seen in that a much smaller type of construction can be created, since surfaces for applying a shield, such as for example in the form of a frame with a cover or a shroud, are not additionally required. The saving of the shielding parts and the reduced surface area of the printed circuit board have the effect of producing a positive balance of costs.

Furthermore, the invention relates to a combination of a printed circuit board, on which at least one electric circuit comprising a number of components is created, with a first, electrically insulating layer and a second, grounded, full-surface, electrically conductive layer, which acts as a shield, the first, electrically insulating layer being applied to the whole surface of the printed circuit board and the second, grounded, electrically conductive layer, which acts as a shield, being applied to the whole surface of the first, electrically insulating layer in such a way that suitable recesses corresponding to the number of components are provided.

The combination of the first, electrically insulating layer with the second, grounded, full-surface, electrically conductive layer is an HDI layer. HDI stands for “high density interconnection”.

The establishment of contacts of the individual components with the printed circuit board for the actual interlinking of the individual components with one another is preferably performed by means of laser contacting, preferably directly at the location of the corresponding component. Directly at the location of the component means here that the contact sites of the component are preferably arranged between it and the printed circuit board. This makes it possible to keep the recesses provided in the second, grounded, electrically conductive layer for the corresponding number of components as small as possible with regard to the respective dimensions, so that optimum shielding is achieved.

Further advantages of the present invention are presented on the basis of the following figure, in which:

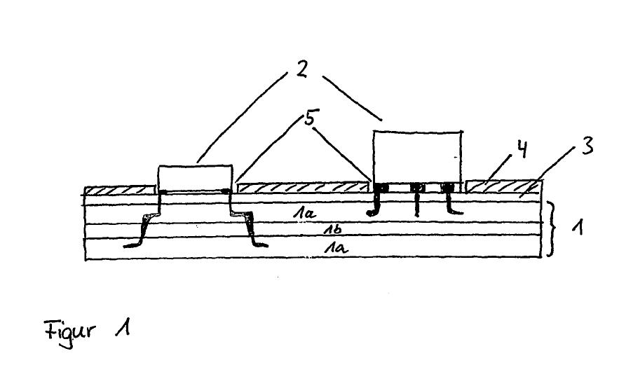

FIG. 1 shows a schematic representation of a combination of a printed circuit board, on which at least one electric circuit comprising a number of components is created, with a first, electrically insulating layer and a second, grounded, full-surface, electrically conductive layer.

FIG. 1 shows a combination of a printed circuit board 1, on which an electric circuit comprising a number of components 2 is created. A first electrically insulating layer 3 is applied to the whole surface of the printed circuit board 1, i.e. this layer 3 extends over the entire surface area of the printed circuit board 1. The layer 3 preferably consists of epoxy resin and has a thickness in the range of 20 μm-60 μm, preferably of approximately 40 μm. The second, grounded, electrically conductive layer 4 is applied to this first layer 3. The layer 4 has recesses 5 corresponding to the number of components 2. The layer 4 is preferably made of copper. The establishment of the contacts of the components 2 with the printed circuit board 1 is performed directly at the location of the respective components 2, so that the second, grounded, electrically conductive layer 4 can come up very close to the individual components 2, or the recesses 5 can be kept very small with regard to their dimensions. Accordingly, shielding over as wide an area as possible is achieved by means of the second, grounded, electrically conductive layer 4. As already described, contacts between the components 2 and the printed circuit board are preferably established by means of a laser technique. With the aid of the laser technique, so-called micro-vias, i.e. “blind holes”, are produced. These are bores which are of an extremely small depth.

The printed circuit board 1 itself likewise comprises a number of layers here, with electrically conductive layers 1a and electrically insulating layers 1b alternating. The electrically conductive layers 1a preferably consist of copper, while the electrically insulating layers 1b consist of an epoxy resin. The actual interlinking of the individual components 2 takes place in the electrically conductive layers 1a of the printed circuit board 1.

1. A method for shielding an electric circuit created on a printed circuit board (1) comprising a number of components (2), a first, electrically insulating layer (3) being applied to the whole surface of the printed circuit board (1) and a second, grounded, electrically conductive layer (4), which acts as a shield, being applied to the whole surface of the first, electrically insulating layer (3) in such a way that suitable recesses (5) for receiving the components corresponding to the number of components (2) are provided.

2. The method as claimed in claim 1, characterized in that the first, electrically insulating layer (3) together with the second, grounded, full-surface, electrically conductive layer (4), which acts as a shield, with suitable recesses for receiving the components (5) corresponding to the number of components (2), is an HDI layer.

3. A combination of a printed circuit board (1), on which at least one electric circuit comprising a number of components (2) is created, with a first, electrically insulating layer (3) and a second, grounded, full-surface, electrically conductive layer (4), which acts as a shield, the first electrically insulating layer (3) being applied to the whole surface of the printed circuit board (1) and the second, grounded, electrically conductive layer (4), which acts as a shield, being applied to the whole surface of the first, electrically insulating layer (3) in such a way that suitable recesses for receiving the components (5) corresponding to the number of components (2) are provided.
